(19) United States
(12) Patent Application Publication
(10) Pub. No.: US 2011/0146746 A1
(43) Pub. Date: Jun. 23, 2011

(54) SOLAR ELECTRIC POWER GENERATION SYSTEM AND METHOD OF MONITORING THE SAME

(75) Inventors: Yaow-Ming CHEN, TAIPEI (TW); Kuan-Yu LIU, TAIPEI (TW)

(73) Assignee: NATIONAL TAIWAN UNIVERSITY, TAIPEI (TW)

(21) Appl. No.: 12/719,858

(22) Filed: Mar. 9, 2010

(30) Foreign Application Priority Data
Dec. 23, 2009 (TW) 98144588

(51) Int. Cl. H01L 31/042; G06F 19/00; G01R 31/00

(52) U.S. Cl. 136/244; 702/58

(57) ABSTRACT

A solar electric power generation system includes a photovoltaic array, a voltage sensing transmission unit, a wireless signal receiving device and a diagnosis unit. The photovoltaic array includes photovoltaic modules, each of which transforms solar power into an output voltage. The voltage sensing transmission unit senses the output voltage from each photovoltaic module and transforms the sensed output voltage into a wireless signal. The wireless signal receiving device receives and transforms the wireless signal into transmission data. The diagnosis unit analyzes the transmission data to generate analysis data. A method of monitoring a solar electric power generation system is also disclosed herein.

### RELATED APPLICATIONS

This application claims priority to Taiwan Patent Application Serial Number 98144588, filed Dec. 23, 2009, which is herein incorporated by reference.

### BACKGROUND

1. Technical Field

The present disclosure relates to an electric power generation system and monitoring method thereof. More particularly, the present disclosure relates to a solar electric power generation system and monitoring method thereof.

2. Description of Related Art

In recent years, a photovoltaic cell (PV cell) for transforming solar power into electric power has been researched by many professionals. Moreover, the research and development of the solar power technology is further promoted due to the rapid development of fabrication technology. Since the solar electric power generation has advantages such as being free, pollution-free, highly safe and easily maintained, it becomes the most potential power technology and is also a new power developing trend in the future.

In a conventional solar electric power generation system, there is a PV array consisted of many PV modules connected in series and in parallel, which is provided for absorbing the solar energy and transforming it into the electric energy. However, if there is single or numerous modules being inactive, the electric energy transformed by the other normal modules will be affected such that the efficiency of the whole system decreases.

For example, FIG. 1 is a diagram of an operating structure of a conventional PV array consisted of two PV modules connected in series. Since the PV array 100 is consisted of two PV modules (1^{st} module and 2^{nd} module) connected in series, the output voltage V_{T} of the PV array 100 is a sum of the output voltages (V₁ and V₂) of the PV modules, i.e. V_{T}=V₁+V₂, and the output current I_{T} of the PV array 100 is equal to the output current of each PV module, i.e. I_{T}=I₁=I₂. In addition, in order to make the PV array 100 have the best power generation efficiency, it is usually necessary that the PV modules having the same current-voltage characteristic curve (I-V curve) are connected in series. FIG. 2 illustrates the respective I-V curves of the foregoing two PV modules and the I-V curve and the power-voltage characteristic curve (P-V curve) of the PV array formed by the foregoing two PV modules connected in series.

In a normal operation, the current of the PV array 100 is the same as those of the 1^{st} module and 2^{nd} module. Thus, if the 1^{st} module and 2^{nd} module have the same maximum power current (I_{MPP}), the maximum output power of the PV array 100 is the sum of the maximum output power of the two modules. On the other hand, the PV modules are connected in series to operate, so the maximum power voltages (V_{MPP}) of both can be different and the PV array 100 can still obtain the maximum output power at the moment. However, once one of the PV modules operates abnormally due to the shadow location or the deterioration, the output power of the PV array 100 will be greatly affected.

Specifically, FIG. 3 illustrates the characteristic curves when the 1^{st} module operates abnormally in the structure shown in FIG. 1. As shown in FIG. 3, the I-V curve deviates from normal and causes the output power to decrease at the same time. Since the currents of the series-connected circuits must be the same, the 2^{nd} module connected in series with the 1^{st} module is involved to be incapable of operating at its maximum power current point. Thus, for the output power decrease of the PV array, not only the output power decrease of the 1^{st} module but also the output power decrease of the 2^{nd} module which cannot operate at its maximum power output point, should be considered. Therefore, the abnormality of single one module would decrease the output power of each series-connected PV module at the same time, and the power generation efficiency of the PV array would decrease accordingly. With the number of the series-connected PV modules increases, the decrease of the power generation efficiency would be more obvious and happen more easily.

FIG. 4 is a diagram of an operating structure of a conventional PV array consisted of two PV modules connected in parallel. Since the PV array 200 is consisted of two PV modules (1^{st} module and 2^{nd} module) connected in parallel, the output voltage V_{T} of the PV array 200 is equal to the output voltage of each PV module, i.e. V_{T}=V₁=V₂, and the output current I_{T} of the PV array 200 is a sum of the output currents (I₁ and I₂) of the PV modules, i.e. I_{T}=I₁+I₂.

FIG. 5 illustrates the respective I-V curves of the foregoing two PV modules and the I-V curve and the P-V curve of the PV array formed by the foregoing two PV modules connected in parallel. When the 1^{st} module and 2^{nd} module have the same maximum power voltage (V_{MPP}), the PV array 200 can operate at the maximum power voltage and the maximum output power of the PV array 200 is the sum of the maximum output power of the two modules. The PV modules are connected in parallel to operate, so the maximum power voltages (I_{MPP}) of both can be different. Similarly, when one of the PV modules operates abnormally, the output power of the PV array 200 will be greatly affected as well.

Specifically, FIG. 6 illustrates the characteristic curves when the 1^{st} module operates abnormally in the structure shown in FIG. 4. As shown in FIG. 6, the I-V curve also deviates from normal and causes the output power to decrease at the same time. Since the voltages of the parallel-connected circuits must be the same, the 2^{nd} module connected in parallel with the 1^{st} module is involved to be incapable of operating at its maximum power voltage point. Thus, for the output power decrease of the PV array, the output power decrease of the 1^{st} module and the output power decrease of the 2^{nd} module which cannot operate at its maximum power output point should be considered at the same time. Therefore, the abnormality of single one module would decrease the output power of each parallel-connected PV module at the same time, and the power generation efficiency of the PV array would decrease accordingly. With the number of the parallel-connected PV modules increases, the decrease of the power generation efficiency would be more obvious and happen more easily.

In conclusion, in regard to the output power of the PV array, if there is an abnormal PV module in a normally operating PV array, the P-V curve of the series-connected PV modules will have the change such as the P-V curve in FIG. 2 decreasing to the P-V curve in FIG. 3. Moreover, the series-connected PV modules may be connected in parallel with the other series-connected PV modules, so the change such as the P-V curve in FIG. 5 decreasing to the P-V curve in FIG. 6 may also be caused. It is understood that in the PV array consisted of several PV modules connected in series and in parallel, the maximum output power of the PV array will apparently be smaller than that in the normal condition. Especially when the number of PV modules connected in series and in parallel is getting more and more, the situation of the maximum output power point descending occurs more easily and the loss of the electric power generation is also severe.

Since the solar electric power generation system at present usually has an inverter connected with the PV array and the inverter is utilized to monitor the power generation efficiency of the whole system, whether the PV array operates abnormally and whether the power generation efficiency of the whole system descends cannot be aware. Even if the power generation efficiency descending is aware, the true reason to the descent cannot be found. For the smaller PV array, the PV modules may be checked one by one to see if any one operates abnormally; however, if the PV array is large, a great amount of the manpower and time will be necessary and the economical benefit cannot be met.

For the foregoing reasons, there is a need to solve the problems that how to detect the operating conditions of the PV modules in real time so as to change the abnormal module, to ensure the solar electric power generation system keeps high efficiency and high reliability.

### SUMMARY

In accordance with one embodiment of the present invention, a solar electric power generation system is provided. The solar electric power generation system includes a photovoltaic array, a voltage sensing transmission unit, a wireless signal receiving device and a diagnosis unit. The photovoltaic array includes a plurality of photovoltaic modules, and each of the photovoltaic modules is configured to transform solar power into an output voltage. The voltage sensing transmission unit is configured for sensing the output voltage generated by each of the photovoltaic modules and transforming the sensed output voltage into at least one wireless signal. The wireless signal receiving device is configured for receiving the wireless signal and transforming the wireless signal into transmission data. The diagnosis unit is configured for analyzing the transmission data generated by the wireless signal receiving device to generate analysis data.

In accordance with another embodiment of the present invention, a method of monitoring a solar electric power generation system is provided, in which the solar electric power generation system includes a plurality of photovoltaic modules, and each of the photovoltaic modules is configured to transform solar power into an output voltage. The method includes the steps of: sensing the output voltages generated by the photovoltaic modules to generate at least one sensing voltage signal; encoding the sensing voltage signal to generate at least one encoding signal; transforming the encoding signal into at least one wireless signal; receiving and transforming the wireless signal into transmission data; and utilizing a diagnosis unit to analyze the transmission data to generate analysis data.

In accordance with yet another embodiment of the present invention, a solar electric power generation system is provided. The solar electric power generation system includes a plurality of photovoltaic module groups, a plurality of voltage sensing elements, a plurality of data processing units, a plurality of wireless signal transmitting devices, a wireless signal receiving device and a diagnosis unit. Each of the photovoltaic module groups includes a plurality of photovoltaic modules connected in series, and the photovoltaic modules are configured to transform solar power into a plurality of group output voltages. The voltage sensing elements are configured for sensing the group output voltages to generate a plurality of sensing voltage signals. The data processing units are configured for encoding the sensing voltage signals to generate a plurality of encoding signals. The wireless signal transmitting devices are configured for transforming the encoding signals into a plurality of wireless signals. The wireless signal receiving device are configured for receiving the wireless signals and transforming the wireless signals into transmission data. The diagnosis unit is configured for analyzing the transmission data generated by the wireless signal receiving device to generate analysis data.

In accordance with still another embodiment of the present invention, a solar electric power generation system is provided. The solar electric power generation system includes a plurality of photovoltaic modules, a plurality of voltage sensing elements, a data processing unit, a wireless signal transmitting device, a wireless signal receiving device and a diagnosis unit. The photovoltaic modules are configured for transforming solar power into a plurality of output voltages. The voltage sensing elements are configured for sensing the output voltages to generate a plurality of sensing voltage signals. The data processing unit is configured for encoding the sensing voltage signals to generate an encoding signal. The wireless signal transmitting device is configured for transforming the encoding signal into a wireless signal. The wireless signal receiving device is configured for receiving the wireless signal and transforming the wireless signal into transmission data. The diagnosis unit is configured for analyzing the transmission data generated by the wireless signal receiving device to generate analysis data.

It is to be understood that both the foregoing general description and the following detailed description are by examples, and are intended to provide further explanation of the invention as claimed.

### BRIEF DESCRIPTION OF THE DRAWINGS

The disclosure can be more fully understood by reading the following detailed description of the embodiments, with reference to the accompanying drawings as follows:

FIG. 1 is a diagram of an operating structure of a conventional PV array consisted of two PV modules connected in series;

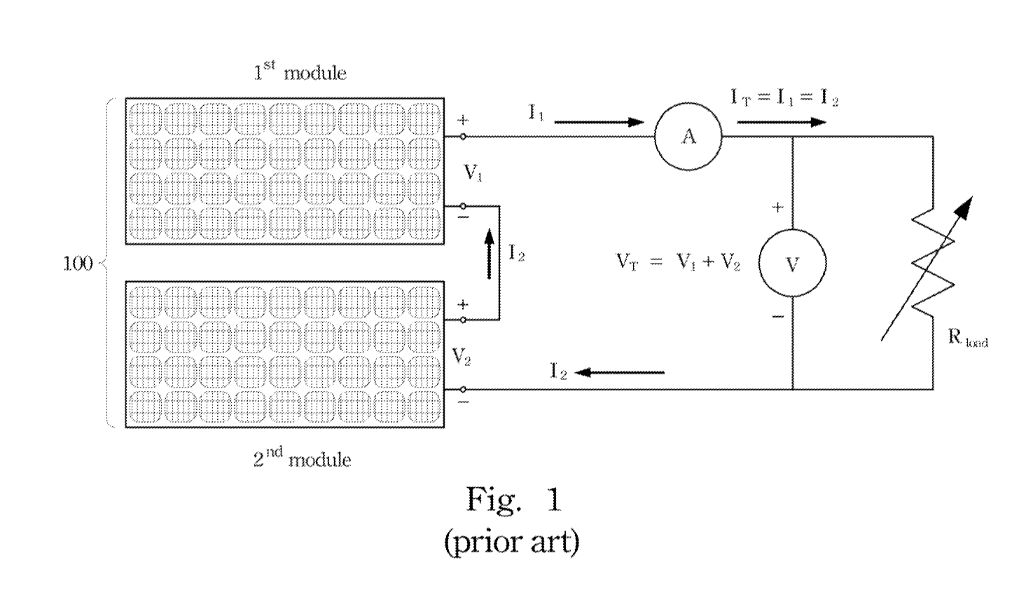

FIG. 2 illustrates the respective I-V curves of the foregoing two PV modules and the I-V curve and the power-voltage characteristic curve (P-V curve) of the PV array formed by the foregoing two PV modules connected in series;

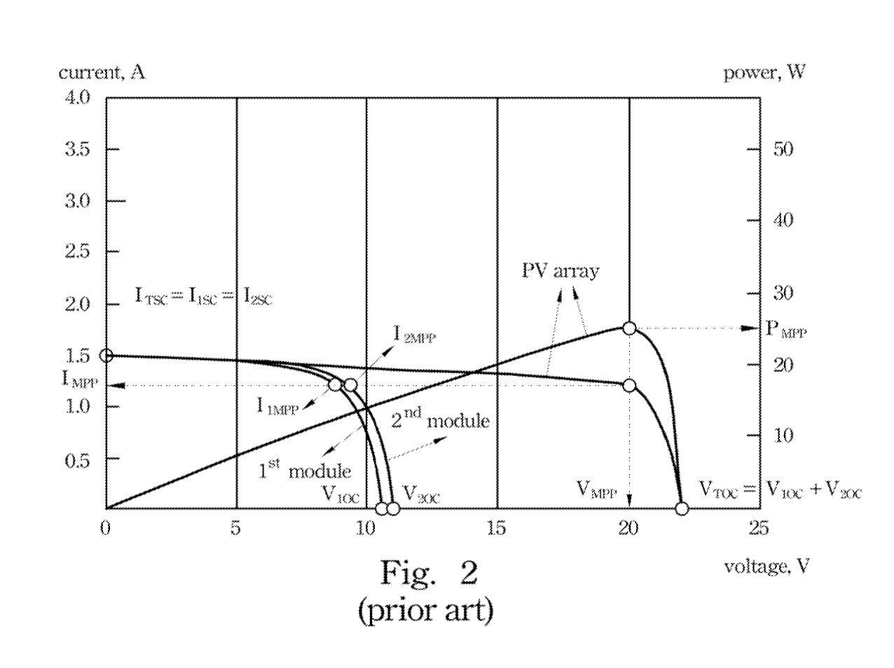

FIG. 3 illustrates the characteristic curves when the 1^{st} module operates abnormally in the structure shown in FIG. 1;

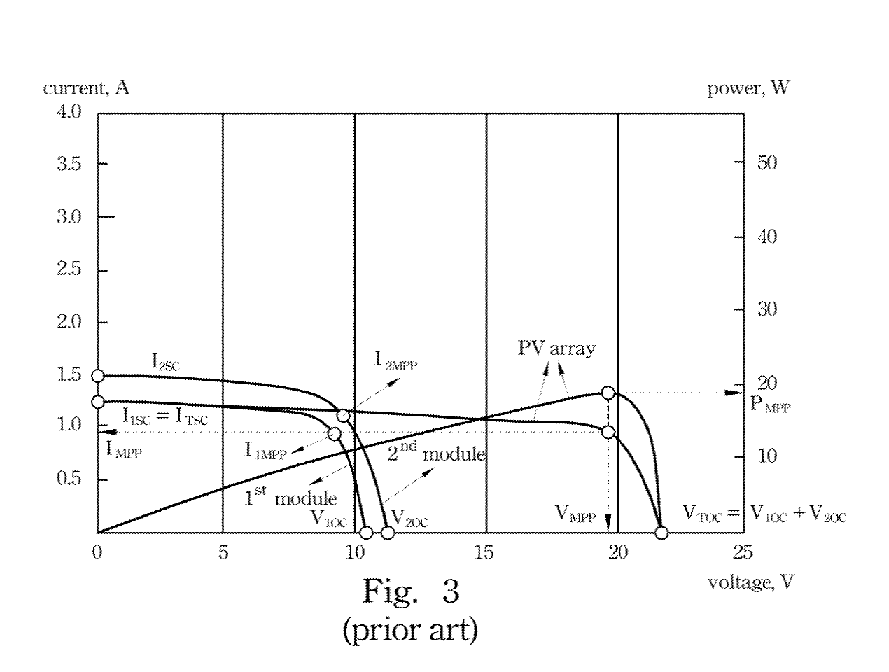

FIG. 4 is a diagram of an operating structure of a conventional PV array consisted of two PV modules connected in parallel;

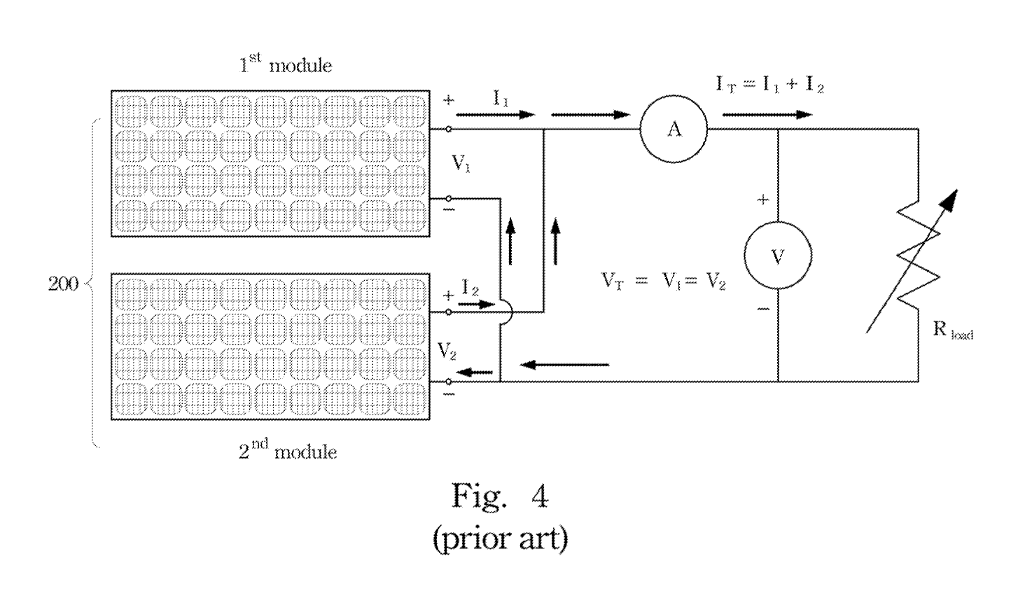

FIG. 5 illustrates the respective I-V curves of the foregoing two PV modules and the I-V curve and the P-V curve of the PV array formed by the foregoing two PV modules connected in parallel;

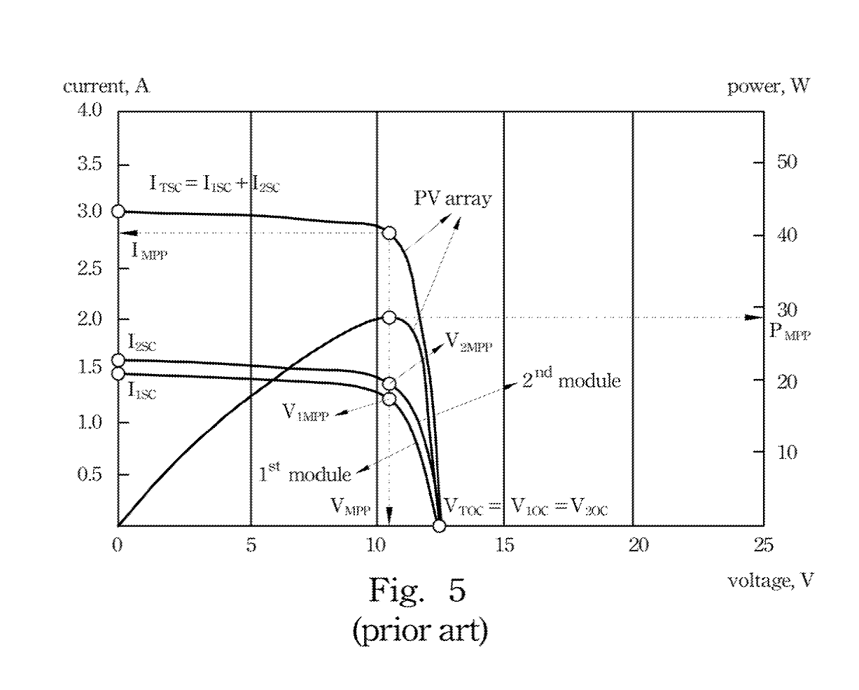

FIG. 6 illustrates the characteristic curves when the 1^{st} module operates abnormally in the structure shown in FIG. 4;

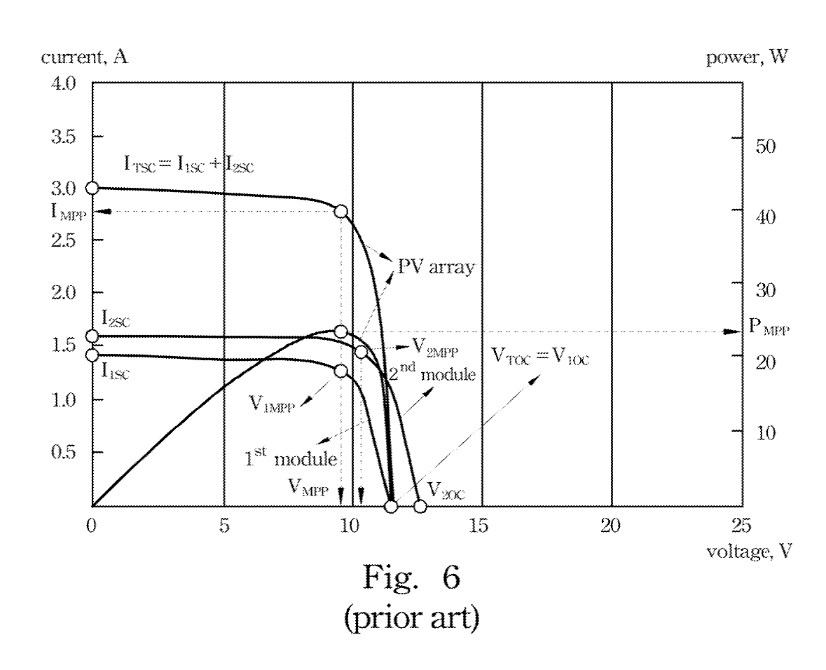

FIG. 7 is a diagram of a solar electric power generation system according to one embodiment of the present invention;

FIG. 8 is a specific diagram of the solar electric power generation system as shown in FIG. 7 according to a first embodiment of the present invention;

FIG. 9 is circuit diagram of a voltage sensing element according to one embodiment of the present invention;

FIG. 10 is a specific diagram of the solar electric power generation is system as shown in FIG. 7 according to a second embodiment of the present invention;

FIG. 11 is a specific diagram of the solar electric power generation system as shown in FIG. 7 according to a third embodiment of the present invention;

FIG. 12 is a specific diagram of the solar electric power generation system as shown in FIG. 7 according to a fourth embodiment of the present invention;

FIG. 13 is a specific diagram of the solar electric power generation system as shown in FIG. 7 according to a fifth embodiment of the present invention;

FIG. 14 is a diagram of the solar electric power generation system according to another embodiment of the present invention; and

FIG. 15 is a flowchart of a method of monitoring a solar electric power generation system according to one embodiment of the present invention.

### DESCRIPTION OF THE EMBODIMENTS

In the following description, several specific details are presented to provide a thorough understanding of the embodiments of the present invention. One skilled in the relevant art will recognize, however, that the present invention can be practiced without one or more of the specific details, or in combination with or with other components, etc. In other instances, well-known implementations or operations are not shown or described in detail to avoid obscuring aspects of various embodiments of the present invention.

The terms used in this specification generally have their ordinary meanings in the art and in the specific context where each term is used. The use of examples anywhere in this specification, including examples of any terms discussed herein, is illustrative only, and in no way limits the scope and meaning of the invention or of any exemplified term. Likewise, the present invention is not limited to various embodiments given in this specification.

As used herein, the terms “comprising,” “including,” “having,” “containing,” “involving,” and the like are to be understood to be open-ended, i.e., to mean including but not limited to.

Reference throughout the specification to “one embodiment” or “an embodiment” means that a particular feature, structure, implementation, or characteristic described in connection with the embodiment is included in at least one embodiment of the present invention. Thus, uses of the phrases “in one embodiment” or “in an embodiment” in various places throughout the specification are not necessarily all referring to the same embodiment. Furthermore, the particular features, structures, implementation, or characteristics may be combined in any suitable manner in one or more embodiments.

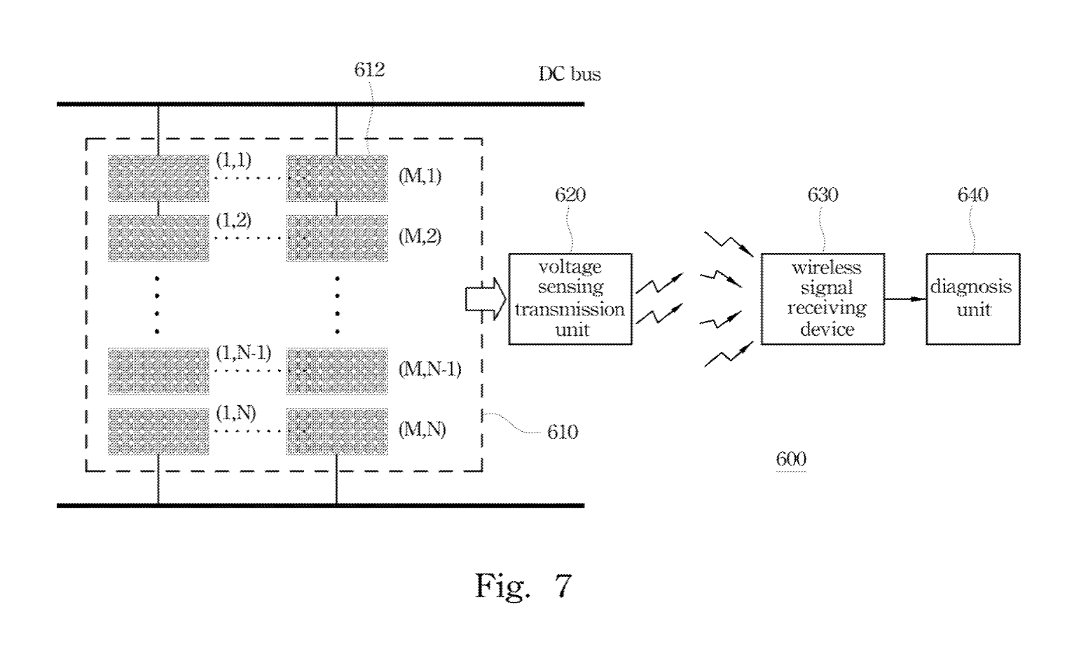

FIG. 7 is a diagram of a solar electric power generation system according to one embodiment of the present invention. As shown in FIG. 7, the solar electric power generation system includes a photovoltaic array (PV array) 610, a voltage sensing transmission unit 620, a wireless signal receiving device 630 and a diagnosis unit 640. The PV array 610 includes a plurality of photovoltaic modules (PV modules) 612, and the PV modules 612 are connected with each other in series and in parallel. Each of the PV modules 612 is configured to transform solar power into an output voltage. In the present embodiment, the PV modules 612 in the PV array 610 are separated into N groups in a series-connected manner and separated into M groups in a parallel-connected manner, to form an N×M PV array. The voltage sensing transmission unit 620 is configured for sensing the output voltage generated by each of the PV modules 612 and transforming the sensed output voltage into at least one wireless signal, and then the voltage sensing transmission unit 620 outputs the wireless signal. The wireless signal receiving device 630 is configured for receiving the wireless signal transmitted by the voltage sensing transmission unit 620 and transforming the wireless signal into transmission data, in which the communication protocol of the wireless signal receiving device 630 may be Bluetooth wireless communication protocol, 802.11b wireless transmission standard or other wireless transmission protocol. The diagnosis unit 640 is configured for analyzing the transmission data generated by the wireless signal receiving device 630 to generate analysis data for administrators to analyze or monitor, in which the diagnosis unit 640 may be implemented by computers, analyzing equipments, etc.

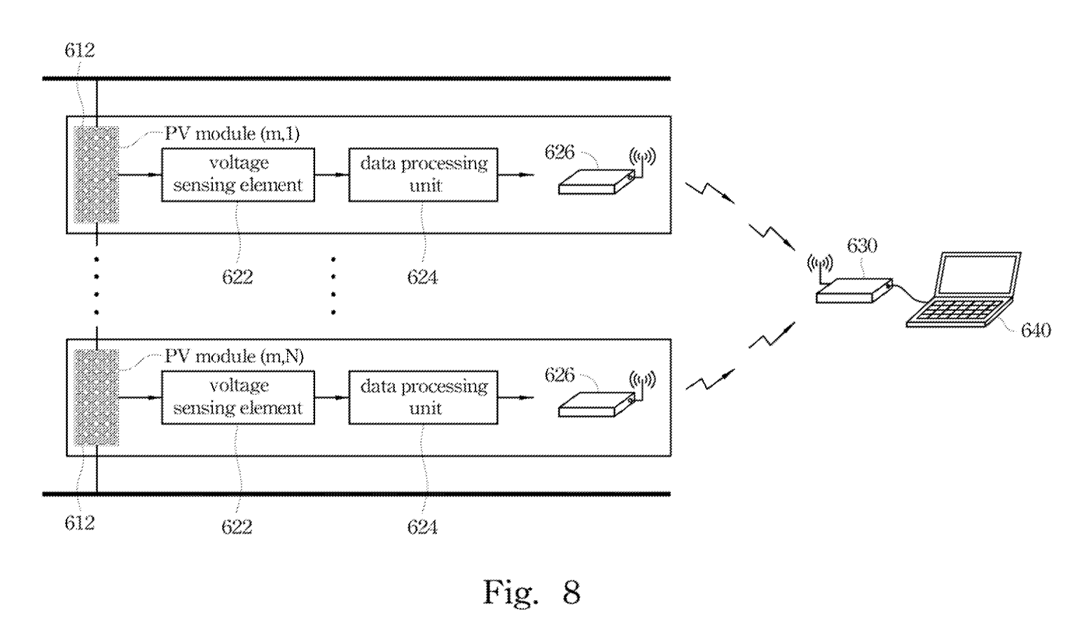

In order to easily describe the embodiments of the present invention, the following embodiments are explained in regard to the m-th group of series-connected PV modules 612. FIG. 8 is a specific diagram of the solar electric power generation system as shown in FIG. 7 according to a first embodiment of the present invention. As shown in FIG. 8, the voltage sensing transmission unit 620 further includes a plurality of voltage sensing elements 622, a plurality of data processing units 624 and a plurality of wireless signal transmitting devices 626. Specifically, in the m-th group of series-connected PV modules 612, each of the PV modules 612 corresponds to one voltage sensing element 622, one data processing unit 624 and one wireless signal transmitting device 626. The voltage sensing element 622 is configured for sensing the output voltage generated by the PV module 612 and then generates a sensing voltage signal. The data processing unit 624 is configured for encoding the sensing voltage signal to generate an encoding signal. The wireless signal transmitting device 626 is configured for transforming the encoding signal into the wireless signal and transmitting the wireless signal to the wireless signal receiving device 630.

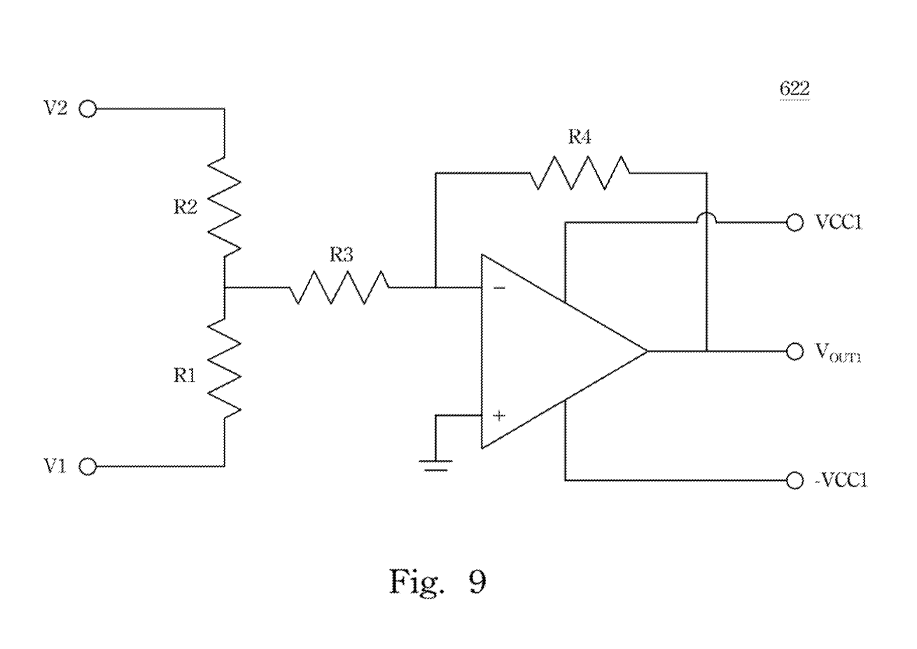

Further, the foregoing voltage sensing element 622 can be an error amplifier circuit including an operational amplifier. FIG. 9 is circuit diagram of a voltage sensing element according to one embodiment of the present invention. As shown in FIG. 9, after being processed by the voltage-dividing resistors R1 and R2 and the negative feedback resistors R3 and R4, the voltage sensing value is delivered from the node V_{OUT1} to the data processing unit 624, the data processing unit 624 encodes the sensing voltage signal outputted from the node V_{OUT1}, and the wireless signal transmitting device 626 transmits the encoding signal. After that, the far-end wireless signal receiving device 630 receives and transforms the wireless signal into the transmission data and transmits the transmission data to the diagnosis unit 640 for being analyzed, stored and diagnosed. Notably, the whole diagnosis process can be performed with a preset time period instead of being continuously performed, so as to save power consumption or required solar power.

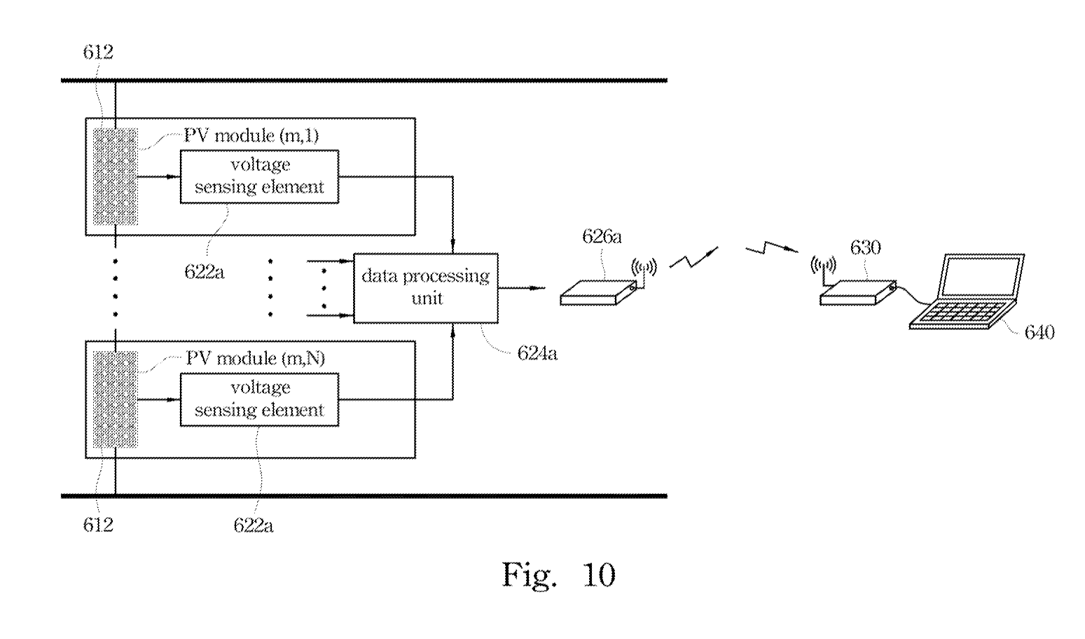

FIG. 10 is a specific diagram of the solar electric power generation system as shown in FIG. 7 according to a second embodiment of the present invention. Compared to FIG. 8, the voltage sensing transmission unit of the present embodiment includes a plurality of voltage sensing elements 622a, a data processing unit 624a and a wireless signal transmitting device 626a. Specifically, in the m-th group of the series-connected PV modules 612, each of the series-connected PV modules 612 corresponds to one voltage sensing element 622a, and the series-connected PV modules 612 simultaneously correspond to the single data processing unit 624a and the single wireless signal transmitting device 626a. The sensing voltage signals generated by all of the voltage sensing elements 622a are transmitted to the common data processing unit 624a for encoding, and then the encoding signal is transmitted from the common wireless signal transmitting device 626a to the wireless signal receiving device 630 and transformed by the wireless signal receiving device 630 into the transmission data. Then, the transmission data are transmitted to the diagnosis unit 640 for being analyzed, stored and diagnosed. Similarly, the whole diagnosis process can be performed with a preset time period instead of being continuously performed.

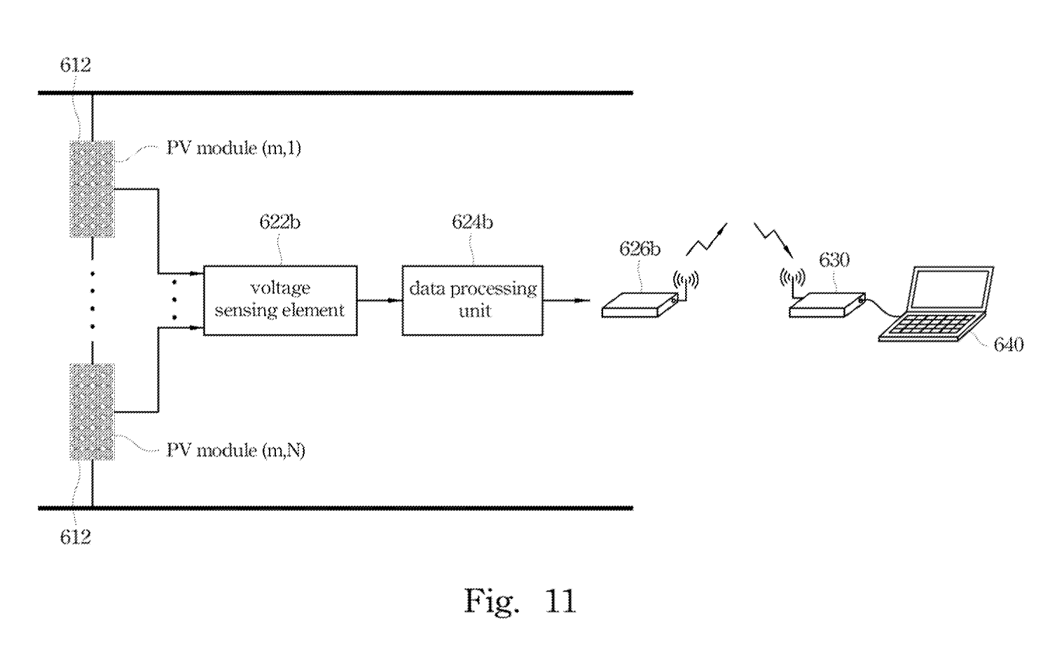

FIG. 11 is a specific diagram of the solar electric power generation system as shown in FIG. 7 according to a third embodiment of the present invention. Compared to FIG. 8, the voltage sensing transmission unit of the present embodiment includes a voltage sensing element 622b, a data processing unit 624b and a wireless signal transmitting device 626b. Specifically, in the m-th group of the series-connected PV modules 612, the series-connected PV modules 612 simultaneously correspond to the single voltage sensing element 622b, the single data processing unit 624b and the single wireless signal transmitting device 626b. In the present embodiment, the common voltage sensing element 622b senses the output voltages generated by the PV modules 612, and then the sensing voltage signal is transmitted to the common data processing unit 624b for encoding. After that, the encoding signal is transmitted from the common wireless signal transmitting device 626b to the wireless signal receiving device 630 and transformed by the wireless signal receiving device 630 into the transmission data. Then; the transmission data are transmitted to the diagnosis unit 640 for being analyzed, stored and diagnosed. Similarly, the whole diagnosis process can be performed with a preset time period instead of being continuously performed.

In addition, except for the foregoing embodiments, it is intended to cover various modifications and similar arrangements included within the spirit and scope of the appended claims, as is understood by a person skilled in the art. For example, the voltage sensing transmission unit also can be implemented by including a single voltage sensing element, a plurality of data processing units and a plurality of wireless signal transmitting devices, by including a single voltage sensing element, a plurality of data processing units and a single wireless signal transmitting device, or by including a single voltage sensing element, a single data processing unit and a plurality of wireless signal transmitting devices.

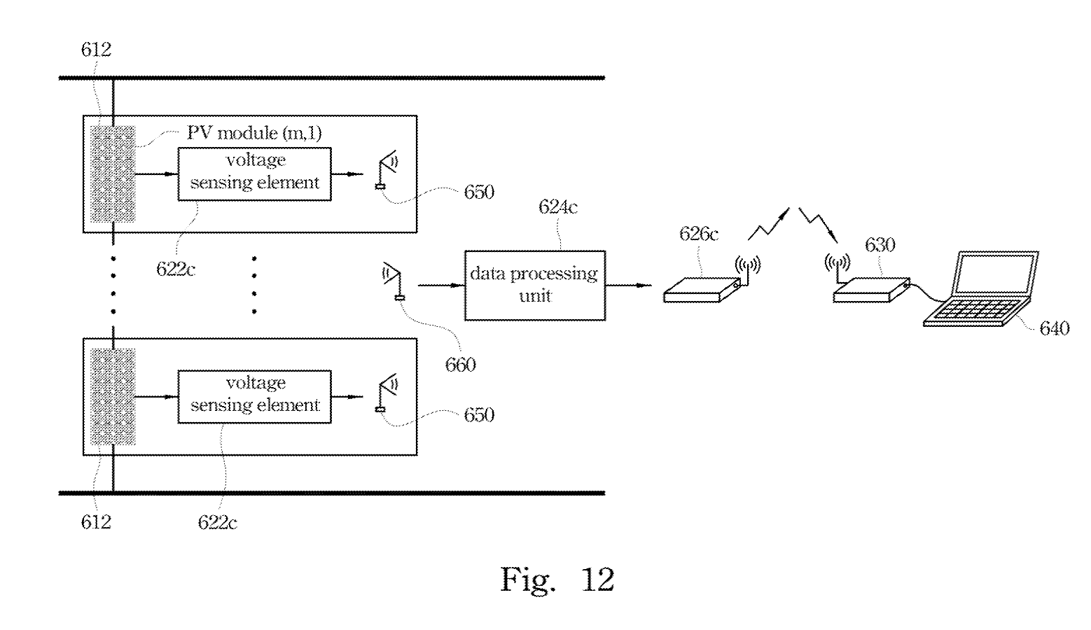

FIG. 12 is a specific diagram of the solar electric power generation system as shown in FIG. 7 according to a fourth embodiment of the present invention. Compared to FIG. 8, the voltage sensing transmission unit of the present embodiment includes a plurality of voltage sensing elements 622c, a data processing unit 624c, a wireless signal transmitting device 626c, a plurality of wireless transmitters 650 and a wireless receiver 660. Specifically, in the m-th group of the series-connected PV modules 612, each of the series-connected PV modules 612 corresponds to one voltage sensing element 622c and one wireless transmitter 650, and all of the series-connected PV modules 612 simultaneously correspond to the single wireless receiver 660, the single data processing unit 624c and the single wireless signal transmitting device 626c. All of the sensing voltage signals generated by the voltage sensing elements 622c are transformed by the corresponding wireless transmitters 650 respectively, and then the wireless transmitters 650 separately transmit a wireless voltage sensing signal. After that, the common wireless receiver 660 receives and transforms the wireless voltage sensing signals into the sensing voltage signal for the common data processing unit 624c and the common wireless signal transmitting device 626c to process, to be then received by the wireless signal receiving device 630 and analyzed and diagnosed by the diagnosis unit 640, so as to complete the entire monitoring or diagnosis process.

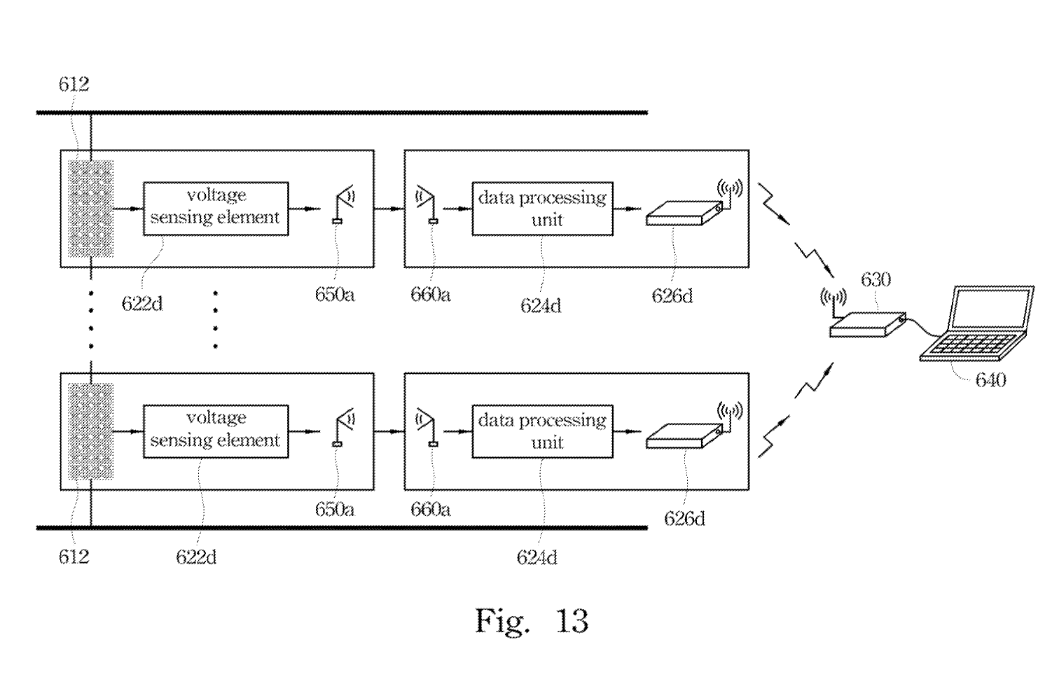

FIG. 13 is a specific diagram of the solar electric power generation system as shown in FIG. 7 according to a fifth embodiment of the present invention. Compared to FIG. 8, the voltage sensing transmission unit of the present embodiment includes a plurality of voltage sensing elements 622d, a plurality of data processing units 624d, a plurality of wireless signal transmitting devices 626d, a plurality of wireless transmitters 650a and a plurality of wireless receiver 660a. Specifically, in the m-th group of the series-connected PV modules 612, each of the series-connected PV modules 612 corresponds to one voltage sensing element 622d, one wireless transmitter 650a, one wireless receiver 660a, one data processing units 624d and one single wireless signal transmitting device 626d. Similarly, the sensing voltage signals generated by the voltage sensing elements 622d are transformed by the corresponding wireless transmitters 650a, and then the wireless transmitters 650a separately transmit the wireless voltage sensing signal. After that, the respective wireless receivers 660a receive and transform the wireless voltage sensing signals into the sensing voltage signals for the respective data processing units 624d and the respective wireless signal transmitting devices 626d to process, to be then received by the wireless signal receiving device 630 and analyzed and diagnosed by the diagnosis unit 640, so as to complete the entire monitoring or diagnosis process.

In addition, except for the foregoing embodiments, it is intended to cover various modifications and similar arrangements included within the spirit and scope of the appended claims, as is understood by a person skilled in the art. For example, the voltage sensing transmission unit also can be implemented by including a single voltage sensing element, a single wireless transmitter, a single receiver, a single data processing unit and a single wireless signal transmitting device.

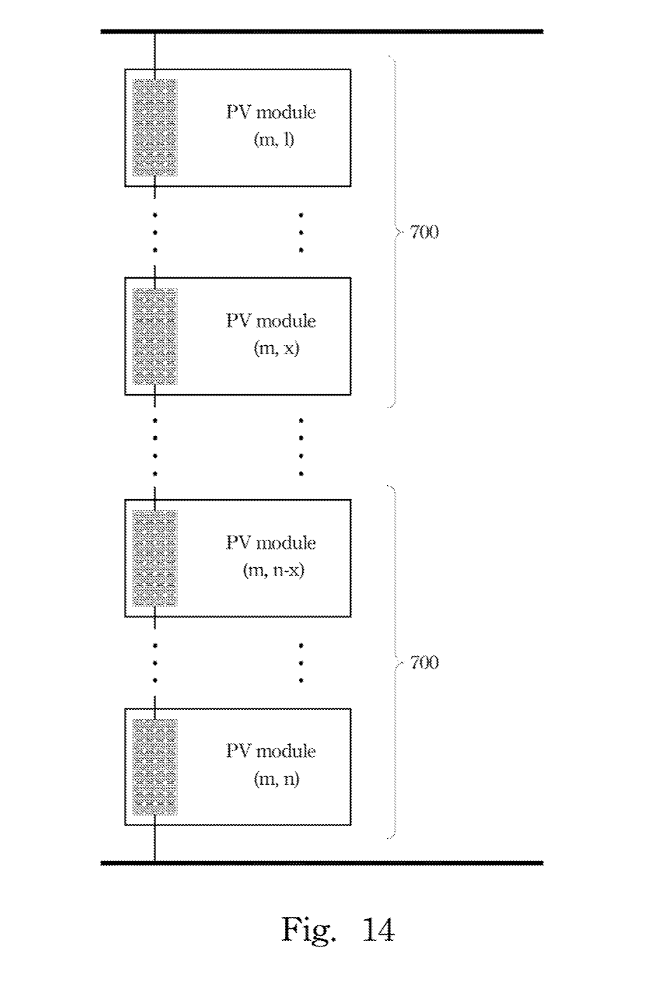

FIG. 14 is a diagram of the solar electric power generation system according to another embodiment of the present invention. As shown in FIG. 14, the PV modules can be separated into a plurality of PV module groups 700 each having a same number or different number of PV modules connected in series. Each of the PV module groups 700 is configured for outputting a group output voltage. The voltage sensing transmission is configured for sensing the group output voltage generated by each of the PV module groups 700 and transforming the sensed group output voltage into the wireless signal. Moreover, after the PV modules are separated into the PV module groups 700, the signals from the PV module groups 700 can be similarly processed by one or more voltage sensing elements, wireless transmitters, wireless receivers, data processing units and wireless signal transmitting devices as mentioned above in the foregoing embodiments. As a result, several PV modules can be operated as one group to be monitored or diagnosed, so as to save the number of the voltage sensing elements, data processing units and wireless signal transmitting devices, or even the number of the wireless transmitters and wireless receivers, for saving the costs.

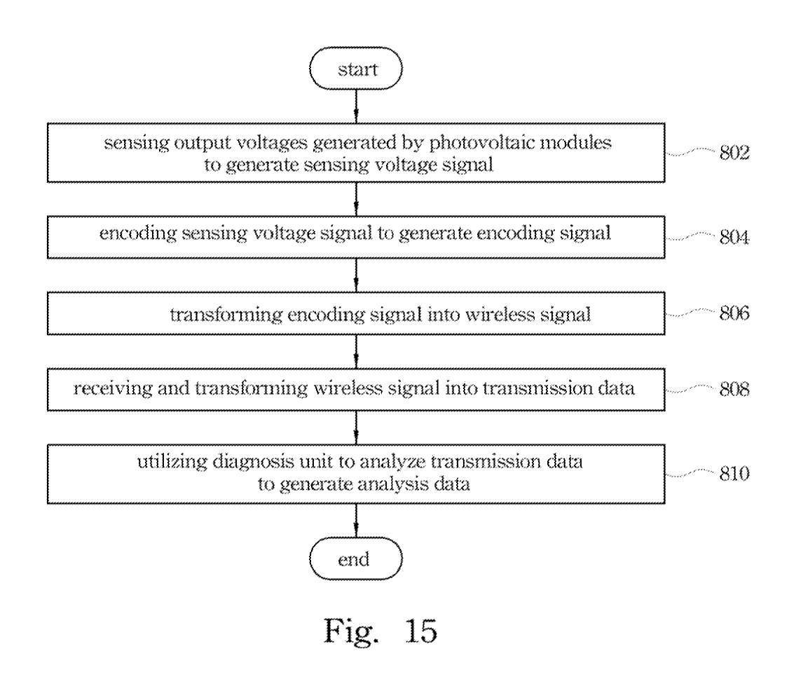

FIG. 15 is a flowchart of a method of monitoring a solar electric power generation system according to one embodiment of the present invention. Refer to FIG. 8 and FIG. 15. First, the output voltages generated by the PV modules 612 are sensed to generate at least one sensing voltage signal (Step 802). Then, the sensing voltage signal is encoded to generate at least one encoding signal (Step 804), in which the step of encoding the sensing voltage signal can be carried out by the data processing unit 624. After that, the encoding signal is transformed into at least one wireless signal (Step 806), in which the step of transforming the encoding signal can be accomplished by the wireless signal transmitting device 626. Afterwards, the wireless signal is received and transformed into the transmission data (Step 808), in which this step can be accomplished by the far-end wireless signal receiving device 630. Then, the diagnosis unit 640 is utilized to analyze the transmission data to generate the analysis data (Step 810).

In addition, the foregoing monitoring method can further include the steps of utilizing at least one wireless transmitter to transform the sensing voltage signal into at least one wireless voltage sensing signal, utilizing the wireless transmitter to transmit the wireless voltage sensing signal, and utilizing at least one wireless receiver to transform the wireless voltage sensing signal into the sensing voltage signal for being encoded to generate the encoding signal.

For the solar electric power generation system, since all the technology at present cannot monitor and diagnose the respective PV modules efficiently and immediately, the PV modules must be checked one by one when any of the PV modules operates abnormally. Moreover, although the U.S. Pat. No. 7,333,916 teaches the monitoring method using the wireless transmission, it discloses the method for monitoring only the entire solar electric power generation system instead of diagnosing and analyzing the respective PV modules, such that the method still cannot sieve out the abnormal PV module from all of the PV modules when the method is performed.

For the foregoing embodiments, the solar electric power generation system and the method of monitoring the same not only can be employed to quickly obtain the operation condition of each PV module by the wireless network transmission, for the diagnosis of the system to sieve out the bad or inefficient module and to replace it in real time, so as to prevent the damaged module from causing the entire system to operate inefficiently, but also can be employed to enhance the efficiency and reliability of the solar electric power generation system.

As is understood by a person skilled in the art, the foregoing embodiments of the present invention are illustrative of the present invention rather than limiting of the present invention. It is intended to cover various modifications and similar arrangements included within the spirit and scope of the appended claims, the scope of which should be accorded with the broadest interpretation so as to encompass all such modifications and similar structures.

What is claimed is:

1. A solar electric power generation system, comprising:
a photovoltaic array comprising a plurality of photovoltaic modules each configured to transform solar power into an output voltage;
a voltage sensing transmission unit for sensing the output voltage generated by each of the photovoltaic modules and transforming the sensed output voltage into at least one wireless signal;
a wireless signal receiving device for receiving the wireless signal and transforming the wireless signal into transmission data; and
a diagnosis unit for analyzing the transmission data generated by the wireless signal receiving device to generate analysis data.

2. The solar electric power generation system as claimed in claim 1, wherein the voltage sensing transmission unit comprises:
at least one voltage sensing element for sensing the output voltage generated by each of the photovoltaic modules to generate a sensing voltage signal;
at least one data processing unit for encoding the sensing voltage signal to generate an encoding signal; and
at least one wireless signal transmitting device for transforming the encoding signal into the wireless signal and transmitting the wireless signal to the wireless signal receiving device.

3. The solar electric power generation system as claimed in claim 1, wherein the voltage sensing transmission unit comprises:
a plurality of voltage sensing elements for sensing the output voltages generated by the photovoltaic modules to generate a plurality of sensing voltage signals;
a plurality of data processing units for encoding the sensing voltage signals to generate a plurality of encoding signals; and
a plurality of wireless signal transmitting devices for transforming the encoding signals respectively into a plurality of wireless signals and transmitting the wireless signals to the wireless signal receiving device.

4. The solar electric power generation system as claimed in claim 1, wherein the voltage sensing transmission unit comprises:
a plurality of voltage sensing elements for sensing the output voltages generated by the photovoltaic modules to generate a plurality of sensing voltage signals;
at least one data processing unit for encoding the sensing voltage signals to generate an encoding signal; and
at least one wireless signal transmitting device for transforming the encoding signal into the wireless signal and transmitting the wireless signal to the wireless signal receiving device.

5. The solar electric power generation system as claimed in claim 1, wherein the voltage sensing transmission unit comprises:
at least one voltage sensing element for sensing the output voltages generated by the photovoltaic modules to generate a plurality of sensing voltage signals;
a plurality of data processing units for encoding the sensing voltage signals respectively to generate an encoding signal; and
at least one wireless signal transmitting device for transforming the encoding signal into the wireless signal and transmitting the wireless signal to the wireless signal receiving device.

6. The solar electric power generation system as claimed in claim 1, wherein the voltage sensing transmission unit comprises:
at least one voltage sensing element for sensing the output voltages generated by the photovoltaic modules to generate a sensing voltage signal;
at least one data processing unit for encoding the sensing voltage signal to generate a plurality of encoding signals; and
a plurality of wireless signal transmitting devices for transforming the encoding signals respectively into a plurality of wireless signals and transmitting the wireless signals to the wireless signal receiving device.

7. The solar electric power generation system as claimed in claim 1, wherein the voltage sensing transmission unit comprises:
at least one voltage sensing element for sensing the output voltage generated by each of the photovoltaic modules to generate a sensing voltage signal;
at least one wireless transmitter for transforming the sensing voltage signal to transmit a wireless voltage sensing signal;
at least one wireless receiver for receiving the wireless voltage sensing signal and transforming the wireless voltage sensing signal into the sensing voltage signal;
at least one data processing unit for encoding the sensing voltage signal to generate an encoding signal; and
at least one wireless signal transmitting device for transforming the encoding signal into the wireless signal and transmitting the wireless signal to the wireless signal receiving device.

8. The solar electric power generation system as claimed in claim 1, wherein the voltage sensing transmission unit comprises:
a plurality of voltage sensing elements for sensing the output voltages generated by the photovoltaic modules respectively to generate a plurality of sensing voltage signals;
a plurality of wireless transmitters for transforming the sensing voltage signals respectively to transmit a plurality of wireless voltage sensing signals;
at least one wireless receiver for receiving the wireless voltage sensing signals and transforming the wireless voltage sensing signals into the sensing voltage signal;
at least one data processing unit for encoding the sensing voltage signal to generate an encoding signal; and
at least one wireless signal transmitting device for transforming the encoding signal into the wireless signal and transmitting the wireless signal to the wireless signal receiving device.

9. The solar electric power generation system as claimed in claim 1, wherein the voltage sensing transmission unit comprises:
a plurality of voltage sensing elements for sensing the output voltages generated by the photovoltaic modules respectively to generate a plurality of sensing voltage signals;
a plurality of wireless transmitters for transforming the sensing voltage signals respectively to transmit a plurality of wireless voltage sensing signals;
a plurality of wireless receivers for receiving the wireless voltage sensing signals and transforming the wireless voltage sensing signals into the sensing voltage signals;
a plurality of data processing units for encoding the sensing voltage signals transformed by the wireless receivers to generate a plurality of encoding signals; and
a plurality of wireless signal transmitting devices for transforming the encoding signals into a plurality of wireless signals and transmitting the wireless signals to the wireless signal receiving device.

10. The solar electric power generation system as claimed in claim 1, wherein the photovoltaic modules are separated into a plurality of photovoltaic module groups, each of the photovoltaic module groups is configured to output a group output voltage, and the voltage sensing transmission unit is configured to sense the group output voltage generated by each of the photovoltaic module groups and to transform the sensed group output voltage into the wireless signal.

11. A method of monitoring a solar electric power generation system, the solar electric power generation system comprising a plurality of photovoltaic modules each configured to transform solar power into an output voltage, the method comprises:
sensing the output voltages generated by the photovoltaic modules to generate at least one sensing voltage signal;
encoding the sensing voltage signal to generate at least one encoding signal;
transforming the encoding signal into at least one wireless signal;
to receiving and transforming the wireless signal into transmission data; and
utilizing a diagnosis unit to analyze the transmission data to generate analysis data.

12. The monitoring method as claimed in claim 11, further comprising:
utilizing at least one wireless transmitter to transform the sensing voltage signal into at least one wireless voltage sensing signal;
utilizing the wireless transmitter to transmit the wireless voltage sensing signal; and
utilizing at least one wireless receiver to transform the wireless voltage sensing signal into the sensing voltage signal.

13. A solar electric power generation system, comprising:
a plurality of photovoltaic module groups, each of the photovoltaic module groups comprising a plurality of photovoltaic modules connected in series, the photovoltaic modules configured to transform solar power into a plurality of group output voltages;
a plurality of voltage sensing elements for sensing the group output voltages to generate a plurality of sensing voltage signals;
a plurality of data processing units for encoding the sensing voltage signals to generate a plurality of encoding signals;
a plurality of wireless signal transmitting devices for transforming the encoding signals into a plurality of wireless signals;
a wireless signal receiving device for receiving the wireless signals and transforming the wireless signals into transmission data; and
a diagnosis unit for analyzing the transmission data generated by the wireless signal receiving device to generate analysis data.

14. The solar electric power generation system as claimed in claim 13, further comprising:
a plurality of wireless transmitters for transforming the sensing voltage signals respectively to transmit a plurality of wireless voltage sensing signals; and
a plurality of wireless receivers for receiving the wireless voltage sensing signals and transforming the wireless voltage sensing signals into the sensing voltage signals for the data processing units to encode.

15. A solar electric power generation system, comprising:
a plurality of photovoltaic modules for transforming solar power into a plurality of output voltages;
a plurality of voltage sensing elements for sensing the output voltages to generate a plurality of sensing voltage signals;
a data processing unit for encoding the sensing voltage signals to generate an encoding signal;
a wireless signal transmitting device for transforming the encoding signal into a wireless signal;
a wireless signal receiving device for receiving the wireless signal and transforming the wireless signal into transmission data; and
a diagnosis unit for analyzing the transmission data generated by the wireless signal receiving device to generate analysis data.

16. The solar electric power generation system as claimed in claim 15, further comprising:
a plurality of wireless transmitters for transforming the sensing voltage signals respectively to transmit a plurality of wireless voltage sensing signals; and
a wireless receiver for receiving the wireless voltage sensing signals and transforming the wireless voltage sensing signals into the sensing voltage signals for the data processing units to encode.
